(19) United States
(12) Patent Application Publication
(10) Pub. No.: US 2007/0273391 A1
(43) Pub. Date: Nov. 29, 2007

(54) Loop Resistance Tester

(76) Inventor: John Joseph Corry, Stockport (GB)

Correspondence Address: MCDERMOTT, WILL & EMERY LLP, 227 WEST MONROE STREET, SUITE 4400, CHICAGO, IL, 60606-5096, US

(21) Appl. No.: 10/583,432

(22) PCT Filed: Dec. 20, 2004
(86) PCT No.: PCT/GB04/05340

§ 371 Date: Jun. 14, 2007

(30) Foreign Application Priority Data
Dec. 19, 2003 (GB) 329381.8

(51) Int. Cl. G01R 31/02; G01R 27/14

(52) U.S. Cl. 324/649; 324/691; 324/715

(57) ABSTRACT

There is disclosed a method and apparatus for measuring loop resistance by injecting into the loop through an inductive injection probe a sinusoidal drive signal at a given frequency, preferably of the order of 1 kHz, to produce a predetermined current in the loop, measuring, by a test probe also inductively coupled to the loop, the true RMS drive voltage signal and induced current, and calculating the loop resistance from the measured RMS values. Also disclosed is a method of providing a reference loop of accurately known resistance, and a multi-value reference loop facilitating accurate measurement of fractional loop resistance.

This invention relates to loop resistance testing.

U.S. Pat. No. 6,225,810 discloses a method of loop resistance testing for an electrical cable shield integrity monitoring system in which the shield is in connection with a conducting structure or is connected to itself such that a closed electrical current loop is formed. A test AC signal generator is inductively coupled to the loop and a test or ‘sense’ winding is placed on the loop, inductively coupled to measure the induced loop current. The disclosure is said to be an improvement on the disclosure of U.S. Pat. No. 5,378,992, but appears to measure loop or joint resistance only to an accuracy of ±8%. This is perhaps good enough for testing integrity of cable shielding and joints, but there is a need for making measurements to much greater accuracy.

The present invention provides a method and apparatus for more accurately measuring loop resistance, which can, of course, measure cable shield integrity but which can also be used to measure the resistance of connections of bond wires connected at both ends to a metal structure.

The invention comprises a method for measuring loop resistance comprising:
injecting into the loop through an inductive injection probe a sinusoidal drive signal at a given frequency to produce a predetermined current in the loop;
measuring, by a test probe also inductively coupled to the loop, the true RMS drive signal voltage and induced current; and
calculating the loop resistance from the measured RMS values.

The given frequency may be of the order of 1 kHz, generally higher than the 200 Hz frequency used in the methods disclosed in the above-cited references.

The sinusoidal drive signal may be generated by a microcontroller using a digital to analogue converter, which may be configured to convert a microcontroller generated 0-10V signal to an output voltage in the range 0-200V. This may be supplied to the injection probe through audio amplifier means.

Drive voltage and current may be measured using a commercially available multimeter card, e.g. a PCMCIA digital multimeter card as supplied by National Instruments. Current is measured across a burden resistor, which may have a resistance of 10Ω. The injection and test probes may have a turns ratio of 500:1 to 2000:1, preferably 1000:1 so that the maximum value of the voltage across the burden is of the order of 1 mV.

Both measurements may be made to a resolution of 5½ digits or 21 bits, and the signals digitally filtered to accept only the given frequency.

Such a method can yield measurements of loop resistance to an accuracy well within ±1%.

The invention also comprises apparatus for measuring loop resistance comprising:
sinusoidal drive signal generating means generating a sinusoidal drive signal at a given frequency;
an inductive injection probe adapted to inject said sinusoidal drive signal into the loop;
an inductive test probe adapted to measure the true RMS drive signal voltage and induced current; and
calculating means for calculating the loop resistance from the measured RMS values.

Said signal generating means may generate a signal at a frequency of the order of 1 kHz The frequency is desirably above 200 Hz. The signal generating means may comprise a microcontroller with a digital to analogue converter. The digital to analogue converter may be configured to convert a 0-10V signal to an output voltage in the range 0-200V. The arrangement may comprise audio amplifier means connected to supply the injection probe with the 0-200V signal.

The apparatus may incorporate a multimeter for measuring drive voltage and/or current. A burden resistor may be included across which current is measured. Such resistor may have a nominal resistance of 10Ω.

The injection and test probes may have a turns ratio of between 500:1 and 2000:1, say 1000:1, so that the maximum value of the voltage across the burden resistor is of the order of 1 mV. The apparatus may comprise a digital filter to filter the signals to accept only the given frequency.

A method and apparatus for measuring loop resistance will now be described with reference to the accompanying drawing, of which;

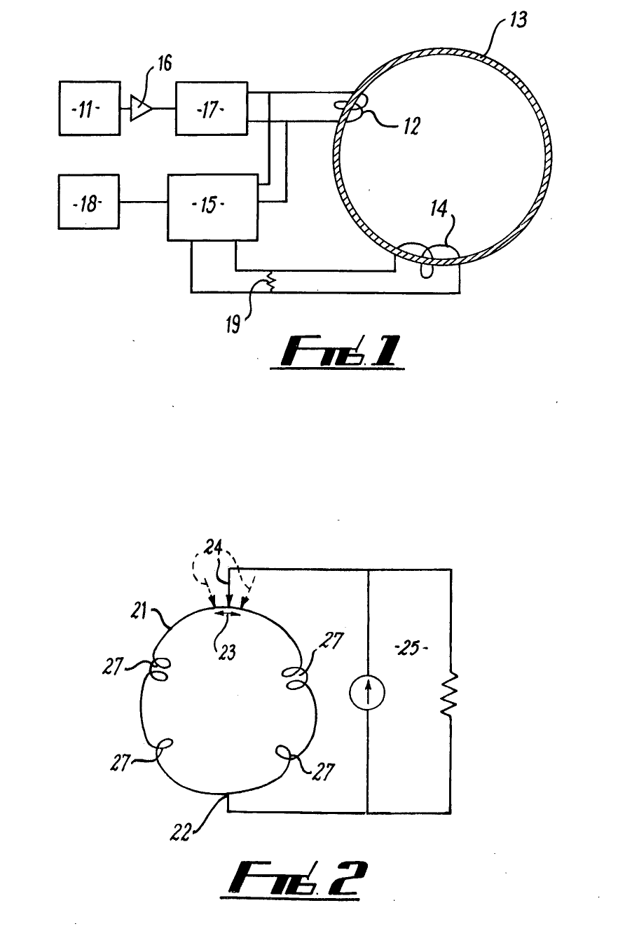

FIG. 1 is a block diagram:

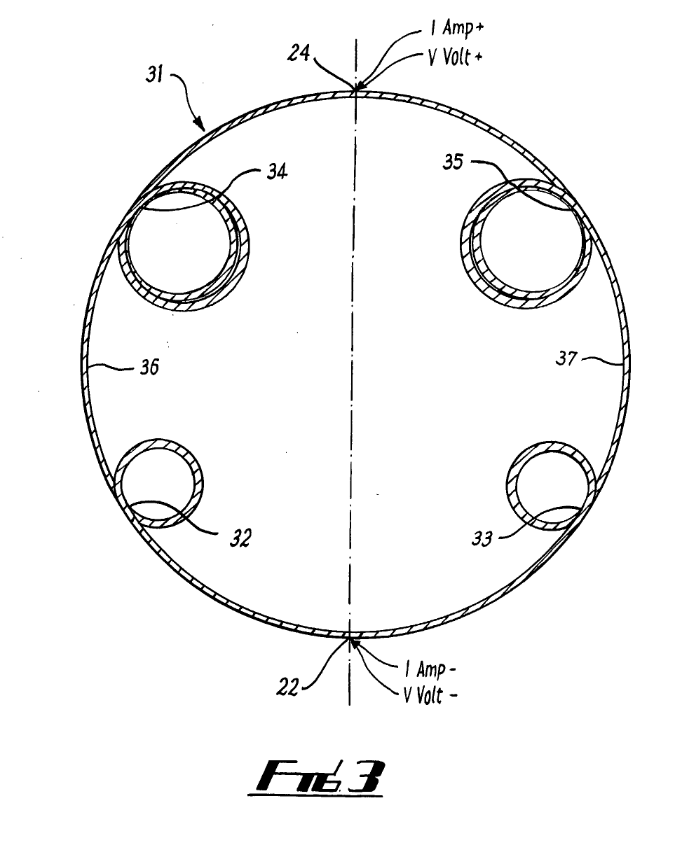

FIG. 2 is a diagrammatic illustration of a method for making a reference loop for calibration purposes; and

FIG. 3 is a diagrammatic illustration of a resistive loop standard providing a range of standard resistances of high accuracy.

FIG. 1 illustrates apparatus for measuring loop resistance comprising:
sinusoidal signal generating means 11 generating a sinusoidal signal at a given frequency;
an inductive injection probe 12 adapted to inject said sinusoidal drive signal into the loop 13;
an inductive test probe 14 adapted to measure the true RMS drive voltage and induced current; and
calculating means 15 for calculating the loop resistance from the measured RMS values.

The sinusoidal drive signal generating means 11 comprise a crystal controlled sine wave generator, generating a signal with a frequency of 1 kHz. The sine wave generator comprises a PIC microcontroller generating a digital signal, converted to an analogue signal by a digital to analogue converter 16, configured to allow a signal selected within the range 0-10V to be applied to the converter 16 allowing an audio amplifier 17 to control the output voltage to the probe to be in the range 0-200V, though in practice a maximum of 50V is usually sufficient for the measurement. The sine wave has some distortion at the crossover point, but this does not affect the measurement.

A control arrangement 18 controls the system until an induced current of 1 A is flowing in the loop 13.

The injection probe 12 is a coil which is placed in inductive relationship with the loop 13, normally surrounding a part of it. The test probe 14 is also a coil, the coils 12 and 14 having a turns ratio of 1000:1, so that a 1V signal fed in by the injection coil 12 produces a 1 mV signal in the test coil 14.

The drive voltage and current measurements are made using a PCMCIA digital multimeter card supplied by National Instruments, incorporated in the calculating means 15, the current being measured across a 10Ω burden resistor 18. Both measurements are made to a resolution of 5½ digits, or 21 bits, and the signals digitally filtered in the calculating means 15 to accept only the 1 kHz frequency.

The arrangement is scalable and will measure higher and lower resistances, depending on the probe turns ratio, injection voltage and induced current.

One advantage over prior art arrangements for measuring loop resistance is that the probes can be small, facilitating access to restricted spaces. Another advantage is the substantially improved accuracy with which the measurement can be effected. Measurement of loop resistance to within ±1% is easily achieved, as compared to ±8% for the best prior art method, commonly used in the aircraft industry for cable shield integrity monitoring and other measurements.

The arrangement is so accurate that a problem has been experienced in finding a method of calibration. The National Physical Laboratory does not have test loops of known resistance. However, as an ancillary invention to the present invention, which is nonetheless independent of it, there is provided a method for providing a reference loop of accurately known resistance, comprising the steps of:
making a loop of nominal resistance; and
measuring the loop resistance by:
making electrical contact with said loop at a first contact position;
making electrical contact with said loop at a second position approximately 180° around said loop;
measuring the resistance of said loop between the contacts;
altering the position of the second contact point until the measured resistance is a maximum; and
calculating the loop resistance to be four times the maximum measured resistance.

The resistance may be measured in a Wheatstone bridge arrangement.

FIG. 2 illustrates this method.

A first contact is made on a reference loop 21 of nominal resistance at a first position 22 on said loop 21. A second contact is made at a second position 23 using a flying lead 24 that can be adjusted in position. A known current is applied, and the resistance between the two contacts is measured. The position of the flying lead 24 is adjusted around the loop 21 until the measured resistance is a maximum. The measurement is made using a Wheatstone bridge arrangement 25. The resistance around the loop is then calculated to be four times the maximum measured resistance on the basis that when the measured resistance is a maximum, the resistances of the two arcs of the loop between the first and second positions are equal (say, to 2R), the measured resistance than being R, the loop resistance then being 4R.

FIG. 3 illustrates a multi-value resistive loop standard 31. In order to verify and calibrate the loop resistance test equipment, it is necessary to check the measured values against a range of loop values. With the inclusion of multiple sub-loops at points 32, 33, 34 and 35, it is possible to create virtual resistances known to the same accuracy as the main loop 31. This means that it is possible to create resistance loops with resistance values that would be difficult to reproduce physically and at an accuracy that would be impossible to achieve through any other method.

The loop 31 is formed from insulated wire, from which the insulation has been removed at positions 22, 24. At points 32, 33, the wire is sub-looped once. At points 34, 35, it is sub-looped twice.

Using the injection and current measuring positions 36, 37, the resistance can be measured as above described when the induced current is set, say, to 1 amp. If the current measuring clamp is now moved to position 32, two conductors will pass through the clamp. If the system adjusts the injected voltage so that the required current of 1 amp still passes through the clamp, each conductor will be carrying 0.5 amps.

The system assumes that 1 amp is flowing through the total loop resistance, and calculates the resistance accordingly. However, the voltage required to induce 0.5 amps to flow is half that required to induce 1 amp to flow and therefore the measured resistance is exactly half of the total loop resistance. Exactly the same thing happens if the injection clamp sees two conductors and the current measuring clamp sees only one.

If the current measuring clamp is now moved to position 34, three conductors will pass through the clamp, carrying a total of 1 amp, each conductor, therefore, carrying ⅓ amp. Thus the system assumes that 1 amp is flowing through the total loop resistance, and the measured resistance is calculated at exactly one third of the total loop resistance.

By putting the injection clamp at position 33 and the current measuring clamp at position 34, the resistance is calculated as one sixth of the total loop resistance, and by putting the clamps at positions 34 and 35, the measured resistance is one ninth of the total loop resistance.

The table shows the exact resistance ratios available using the loop shown in FIG. 3. Any desired number of sub-loops can be added to give virtual loops of smaller resistances.

| | | Resistance |
|---|---|---|
| Injection clamp position | Current clamp position | value measured |
| Position 36 | Position 37 | Total loop resistance R |
| Position 36 | Position 32 | R/2 |
| Position 36 | Position 34 | R/3 |
| Position 32 | Position 33 | R/4 |
| Position 33 | Position 34 | R/6 |
| Position 34 | Position 35 | R/9 |

1. A method for measuring loop resistance comprising:
injecting into the loop through an inductive injection probe a sinusoidal drive signal at a given frequency to produce a predetermined current in the loop;
measuring, by a test probe also inductively coupled to the loop, the true RMS drive signal voltage and induced current; and
calculating the loop resistance from the measured RMS values.

2. A method according to claim 1, in which the given frequency is of the order of 1 kHz.

3. A method according to claim 1, in which the sinusoidal signal is generated by a microcontroller using a digital to analogue converter.

4. A method according to claim 3, in which the converter is configured to convert a microcontroller generated 0-10V signal to an output voltage in the range 0 200V.

5. A method according to claim 4, in which the output voltage is supplied to the injection probe through audio amplifier means.

6. A method according to claim 1, in which drive signal voltage and induced current are measured using a multimeter arrangement.

7. A method according to claim 1, in which current is measured across a burden resistor.

8. A method according to claim 7, in which the burden resistor has a value of 10Ω.

9. A method according to claim 1, in which the injection and test probes have a turns ratio of 1000:1.

10. A method according to claim 1, in which measurements are made to a resolution of 5½ digits or 21 bits.

11. A method according to claim 1, in which the measured signals are digitally filtered to accept only the given frequency.

12. Apparatus for measuring loop resistance, comprising:
sinusoidal drive signal generating means generating a sinusoidal drive signal at a given frequency;
an inductive injection probe adapted to inject said sinusoidal drive signal into the loop;
an inductive test probe adapted to measure the true RMS drive signal voltage and induced current; and
calculating means for calculating the loop resistance from the measured RMS values.

13. Apparatus according to claim 12, in which the drive signal generating means generates a drive signal above 200 Hz.

14. Apparatus according to 12, in which the drive signal generating means generates a drive signal at a frequency of the order of 1 kHz.

15. Apparatus according to claim 12, in which the drive signal generating means comprise a microcontroller with a digital to analogue converter.

16. Apparatus according to claim 15, in which the digital to analogue converter is configured to convert a 0-10V signal to an output voltage in the range 0-200V.

17. Apparatus according to claim 12, comprising audio amplifier means connected to supply the injection probe.

18. Apparatus according to claim 12, incorporating a multimeter for measuring drive voltage and/or induced current.

19. Apparatus according to claim 18, including a burden resistor across which induced current is measured.

20. Apparatus according to claim 19, in which the burden resistor has a value of 10Ω.

21. Apparatus according to claim 12, in which the injection and test probes have a turns ratio of between 500:1 and 2000:1.

22. Apparatus according to claim 21, in which the injection and test probes have a turns ratio of 1000:1.

23. Apparatus according to claim 12, comprising a digital filter to filter the signals to accept only the given frequency.

24. A method for providing a reference loop of accurately known resistance, comprising the steps of:
making a loop of nominal resistance; and
measuring the loop resistance by:
making electrical contact with said loop at a first contact position;
making electrical contact with said loop at a second position approximately 180° around said loop; and
measuring the resistance of said loop between the contacts;
altering the position of the second contact point until the measured resistance is a maximum, and;
calculating the loop resistance to be four times the maximum measured resistance.

25. A method according to claim 24, in which the resistance is measured in a Wheatstone bridge arrangement.

26. A method according to claim 24, in which the loop has sub-loops facilitating fractional loop resistances.

27. A reference loop of accurately known loop resistance made by a method according to claim 25.

28. A multi-value reference loop of known loop resistance having at least one sub-loop facilitating measurement of fractional loop resistance by providing more than one current path through an injection probe and/or a test probe.
